(19) United States
(12) Patent Application Publication
(10) Pub. No.: US 2013/0154040 A1
(43) Pub. Date: Jun. 20, 2013

(54) PHOTO DETECTORS

(71) Applicants: Chul Huh, Daejeon (KR); Sang Hyeob Kim, Daejeon (KR); Byoung-Jun Park, Iksan (KR); Eun Hye Jang, Daejeon (KR)

(72) Inventors: Chul Huh, Daejeon (KR); Sang Hyeob Kim, Daejeon (KR); Byoung-Jun Park, Iksan (KR); Eun Hye Jang, Daejeon (KR)

(73) Assignee: Electronics and Telecommunications Research Institute, Daejeon (KR)

(21) Appl. No.: 13/612,760

(22) Filed: Sep. 12, 2012

(30) Foreign Application Priority Data
Dec. 20, 2011 (KR) 10-2011-0138138

(51) Int. Cl. H01L 31/0224; B82Y 99/00

(52) U.S. Cl. 257/431; 257/E31.126; 977/954

(57) ABSTRACT

Photo detectors are provided. The photo detector includes a photoelectric conversion layer between a lower carrier transportation layer and an upper carrier transportation layer, and a common electrode on the upper carrier transportation layer opposite to the photoelectric conversion layer. The photoelectric conversion layer includes a plurality of light absorption layers and each of the light absorption layers contains silicon nanocrystals. The silicon nanocrystals in respective ones of the light absorption layers have different sizes from each other.

### CROSS-REFERENCE TO RELATED APPLICATIONS

This U.S. non-provisional patent application claims priority under 35 U.S.C. §119 to Korean Patent Application No. 10-2011-0138138, filed on Dec. 20, 2011, the disclosure of which is hereby incorporated by reference in its entirety.

### BACKGROUND

1. Technical Field

The present disclosure herein relates to photo detectors and, more particularly, to photo detectors having an enhanced photoelectric conversion efficiency.

2. Description of Related Art

Photo detectors, for example, image sensors are semiconductor devices that convert optical signals into electrical signals. The image sensors may include complementary metal-oxide-semiconductor (CMOS) image sensors, and the CMOS image sensors may have some advantages of low fabrication costs, low power consumption, high integration density and high operation speed. Thus, the CMOS image sensors have been continuously developed.

The CMOS image sensors may receive and detect incident lights using a p-n junction photodiode formed of a silicon material. A size of a unit pixel including the p-n junction photodiode has been gradually reduced to obtain a high image resolution and a high-definition image of the CMOS image sensors. That is, various fabrication technologies have been developed to realize highly integrated CMOS image sensors.

However, optical systems including optical lenses may be required to realize the images of objects using the CMOS image sensors. Thus, the sizes of the image sensors may depend on the sizes of the optical lenses. That is, there may be some limitations in improving the integration density of the image sensors. Further, if the unit pixels are too shrunken down, the intensity of the incident light irradiated on a single pixel is reduced to generate a low photocurrent which is difficult to realize the image. Accordingly, high performance image sensors having an enhanced light absorption efficiency and/or an enhanced photoelectric conversion efficiency may be still required to solve the above disadvantages.

### SUMMARY

Exemplary embodiments are directed to photo detectors having an enhanced photoelectric conversion efficiency and/or an enhanced light absorption efficiency.

According to some embodiments, a photo detector includes a photoelectric conversion layer between a lower carrier transportation layer and an upper carrier transportation layer, and a common electrode on the upper carrier transportation layer opposite to the photoelectric conversion layer. The photoelectric conversion layer includes a plurality of light absorption layers and each of the light absorption layers contains silicon nanocrystals. The silicon nanocrystals in respective ones of the light absorption layers have different sizes from each other.

In some embodiments, a size of the silicon nanocrystals in each light absorption layer may be gradually increased as the light absorption layer becomes closer to the common electrode.

In some embodiments, each of the light absorption layers includes a silicon nitride layer containing the silicon nanocrystals.

In some embodiments, the photo detector may further include a metal particle layer between the upper carrier transportation layer and the common electrode. The metal particle layer may include metal particles having a size of about a few nanometers to about several hundreds of nanometers. The metal particle layer may include at least one species of gold particles, silver particles and aluminum particles.

In some embodiments, the lower carrier transportation layer may include a semiconductor material doped with impurities of a first conductivity type. The upper carrier transportation layer may include a semiconductor material doped with impurities of a second conductivity type opposite to the first conductivity type.

In some embodiments, the upper carrier transportation layer may include a silicon carbide type material.

In some embodiments, the common electrode may be a conductive electrode including indium tin oxide (ITO), SnO₂, In₂O₃, Cd₂SnO₄ or ZnO.

In some embodiments, the photo detector may further include an upper electrode on the common electrode and a lower electrode under the lower carrier transportation layer. Each of the upper and lower electrodes may include nickel or gold.

According to further embodiments, a photo detector includes a first light absorption layer, a second light absorption layer and a third light absorption layer sequentially stacked on a lower carrier transportation layer, and an upper carrier transportation layer on the third light absorption layer. The first light absorption layer includes first nanocrystals having a first size, the second light absorption layer includes second nanocrystals having a second size greater than the first size, and the third light absorption layer includes third nanocrystals having a third size greater than the second size.

In some embodiments, incident lights may be irradiated onto a top surface of the upper carrier transportation layer opposite to the third light absorption layer.

In some embodiments, each of the first to third light absorption layers may include a silicon nitride layer.

In some embodiments, the first to third nanocrystals may be silicon nanocrystals.

### BRIEF DESCRIPTION OF THE DRAWINGS

Embodiments of the inventive concept will become more apparent in view of the attached drawings and accompanying detailed description.

FIG. 1 is a cross sectional view illustrating a typical photo detector.

FIG. 2 is an enlarged view illustrating a portion ‘A’ of FIG. 1 to describe a light absorption path of the photo detector shown in FIG. 1.

FIG. 3 is a cross sectional view illustrating a photo detector according to some exemplary embodiments.

FIG. 4 is an enlarged view illustrating a portion ‘B’ of FIG. 3 to describe a light absorption path of the photo detector shown in FIG. 3.

FIG. 5 is a cross sectional view illustrating a photo detector according to some exemplary embodiments.

FIG. 6 is a cross sectional view illustrating a photo detector according to some exemplary embodiments.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept will be apparent from the following exemplary embodiments that will be described in more detail with reference to the accompanying drawings. It should be noted, however, that the inventive concept is not limited to the following exemplary embodiments, and may be implemented in different forms. Rather, these embodiments are provided so that this disclosure will be thorough and complete, and will fully convey the scope of the inventive concept to those skilled in the art.

It will be understood that when an element such as a layer, region or substrate is referred to as being “on” another element, it can be directly on the other element or intervening elements may be present. In the drawings, the thicknesses of layers and regions are exaggerated for clarity.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the inventive concepts. Exemplary embodiments of aspects of the present inventive concept explained and illustrated herein include their complementary counterparts.

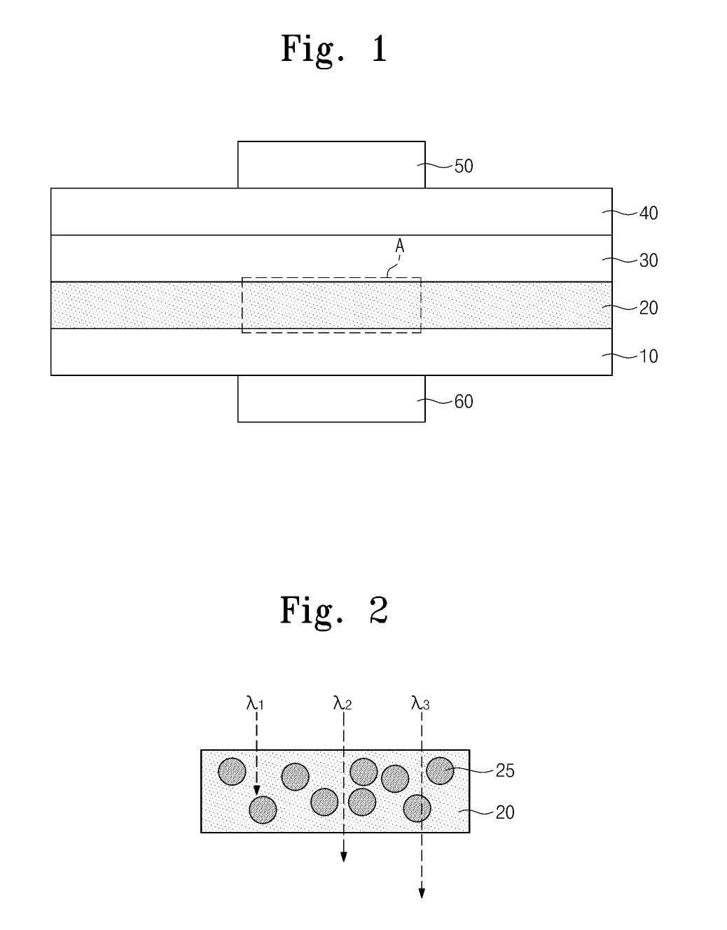

FIG. 1 is a cross sectional view illustrating a typical photo detector, and FIG. 2 is an enlarged view illustrating a portion ‘A’ of FIG. 1 to describe a light absorption path of the photo detector shown in FIG. 1.

Referring to FIG. 1, a typical photo detector may include a lower carrier transportation layer 10, a photoelectric conversion layer 20, an upper carrier transportation layer 30 and a common electrode 40. The photoelectric conversion layer 20, the upper carrier transportation layer 30 and the common electrode 40 may be sequentially stacked on the lower carrier transportation layer 10. In addition, an upper electrode 50 may be disposed on the common electrode 40 opposite to the upper carrier transportation layer 30 and a lower electrode 60 may be disposed under the lower carrier transportation layer 10 opposite to the photoelectric conversion layer 20.

The photoelectric conversion layer 20 may receive external lights to generate electron-hole pairs. The electrons and the holes in the photoelectric conversion layer 20 may be drifted into the upper and lower carrier transportation layers 10 and 30 to generate current. That is, the electrons and the holes in the photoelectric conversion layer 20 may be drifted into the upper and lower carrier transportation layers 10 and 30 and may be converted into an electrical signal that flows through the upper and lower electrodes 50 and 60. Thus, the typical photo detector may convert the external lights into an electrical signal.

Referring to FIG. 2, the photoelectric conversion layer 20 may include nanocrystals 25. The nanocrystals 25 may increase a generation efficiency of the electron-hole pairs in the photoelectric conversion layer 20.

In general, the typical photoelectric conversion layer 20 may be formed of a single layer. Thus, the nanocrystals 25 in the photoelectric conversion layer 20 may be disposed to have a uniform size. In such a case, the photoelectric conversion layer 20 may absorb only the lights having a specific wavelength λ1 that is determined by the size of the nanocrystals 25, and the other lights having different wavelengths λ2 and λ3 from the specific wavelength may pass through the photoelectric conversion layer 20 or may be reflected onto the photoelectric conversion layer 20. As result, when the photoelectric conversion layer 20 may be formed of a single layer including the nanocrystals 25 having a uniform size, there may be some limitations in improving the photoelectric conversion efficiency and/or the light absorption efficiency of the photoelectric conversion layer 20.

Therefore, the following exemplary embodiments may provide photo detectors which are appropriate for improvement of the photoelectric conversion efficiency and/or the light absorption efficiency of a photoelectric conversion layer.

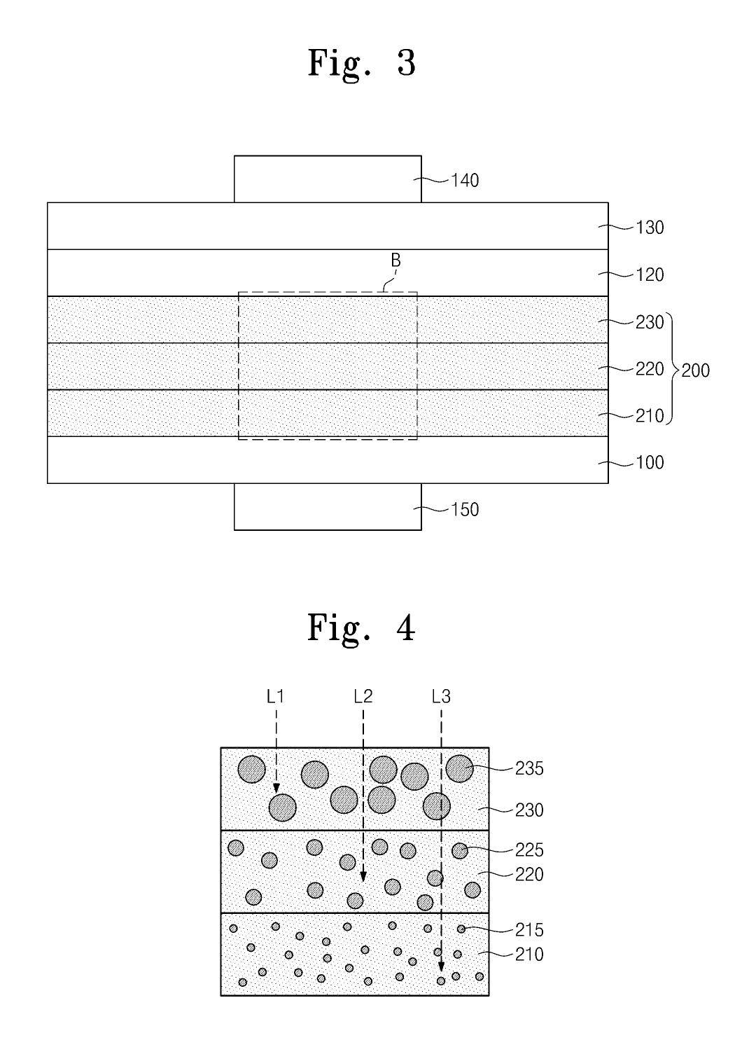

FIG. 3 is a cross sectional view illustrating a photo detector according to some exemplary embodiments, and FIG. 4 is an enlarged view illustrating a portion ‘B’ of FIG. 3 to describe a light absorption path of the photo detector shown in FIG. 3.

Referring to FIG. 3, a photoelectric conversion layer 200 may be disposed on a lower carrier transportation layer 100. The lower carrier transportation layer 100 may be a semiconductor substrate, for example, a silicon substrate. The lower carrier transportation layer 100 may be doped with impurities of a first conductivity type. In some exemplary embodiments, the lower carrier transportation layer 100 may be a P-type substrate.

The photoelectric conversion layer 200 may include a silicon nitride (SiN) layer. The photoelectric conversion layer 200 may further include silicon nanocrystals (Si-NCs). The silicon nanocrystals (Si-NCs) may be contained in the silicon nitride (SiN) layer. The photoelectric conversion layer 200 may have a thickness of about 1 nanometer or greater. In some exemplary embodiments, the silicon nanocrystals (Si-NCs) may have a size of about 1 nanometer to about 10 nanometers. The silicon nanocrystals (Si-NCs) may have diverse shapes such as sphere shapes, tetrahedron shapes, columnar shapes, rod shapes, triangle shapes, disk shapes, tripod shapes, tetrapod shapes, cube shapes, box shapes, star shapes or tube shapes.

The photoelectric conversion layer 200 may have a multi-layered structure. For example, the photoelectric conversion layer 200 may include a first light absorption layer 210, a second light absorption layer 220 and a third light absorption layer 230. The first, second and third light absorption layers 210, 220 and 230 may be sequentially stacked on the lower carrier transportation layer 100. That is, the first light absorption layer 210 may be stacked on the lower carrier transportation layer 100, the second light absorption layer 220 may be stacked on the first light absorption layer 210 opposite to the lower carrier transportation layer 100, and the third light absorption layer 230 may be stacked on the second light absorption layer 220 opposite to the first light absorption layer 210.

Each of the first, second and third light absorption layers 210, 220 and 230 may include silicon nanocrystals (Si-NCs). The silicon nanocrystals (Si-NCs) in the first, second and third light absorption layers 210, 220 and 230 may have different sizes from each other.

The sizes of the Si-NCs in the first, second and third light absorption layers 210, 220 and 230 may gradually increase toward a top surface of the third light absorption layer 230 opposite to the second light absorption layer 220 or toward a bottom surface of the first light absorption layer 210 opposite to the second light absorption layer 220. In some exemplary embodiments, the sizes of the Si-NCs in the first, second and third light absorption layers 210, 220 and 230 may be gradually reduced toward the lower carrier transportation layer 100. That is, the size of the Si-NCs in the second light absorption layer 220 may be less than that of the Si-NCs in the third light absorption layer 230, and the size of the Si-NCs in the first light absorption layer 210 may be less than that of the Si-NCs in the second light absorption layer 220.

The photoelectric conversion layer 200 may be formed using a deposition process, for example, a plasma enhanced chemical vapor deposition (PECVD) process. The photoelectric conversion layer 200 may generate electron-hole pairs in response to incident lights irradiated onto an image sensor including the photoelectric conversion layer 200.

Because the photoelectric conversion layer 200 has the Si-NCs, the photoelectric conversion layer 200 may have a direct transition band structure which is similar to band structures of compound semiconductors. Thus, an energy potential density of the photoelectric conversion layer 200 may increase to provide high efficiency image sensors.

An upper carrier transportation layer 120 may be disposed on the photoelectric conversion layer 200 opposite to the lower carrier transportation layer 100. The upper carrier transportation layer 120 may include a semiconductor material, for example, a silicon carbide type material (SiC or SiCN). The upper carrier transportation layer 120 may be doped with impurities of a second conductivity type opposite to the first conductivity type. In some exemplary embodiments, the upper carrier transportation layer 120 may be doped with N-type impurities. The upper carrier transportation layer 120 may have a thickness of about 1 nanometer or greater.

A common electrode 130 may be disposed on the upper carrier transportation layer 120 opposite to the photoelectric conversion layer 200. The common electrode 130 may be a conductive electrode including indium tin oxide (ITO), SnO₂, In₂O₃, Cd₂SnO₄ or ZnO. The common electrode 130 may have a thickness of about 1 nanometer or greater.

An upper electrode 140 may be disposed on the common electrode 130 opposite to the upper carrier transportation layer 120, and a lower electrode 150 may be disposed under the lower carrier transportation layer 100 opposite to the photoelectric conversion layer 200. Each of the upper and lower electrodes 140 and 150 may include a conductive material, for example, a metal layer such as a nickel (Ni) layer or a gold (Au) layer.

The lower carrier transportation layer 100, the photoelectric conversion layer 200, the upper carrier transportation layer 120, the common electrode 130, and the upper and lower electrodes 140 and 150 may constitute a photo detector.

The photoelectric conversion layer 200 of the photo detector according to the exemplary embodiments may have a multi-layered structure, thereby enhancing light absorption efficiency thereof The photoelectric conversion layer 200 having a multi-layered structure will be described more fully hereinafter with reference to FIG. 4.

Referring to FIG. 4, the photoelectric conversion layer (200 of FIG. 3) may include the first, second and third light absorption layers 210, 220 and 230, as described with reference to FIG. 3. The first light absorption layer 210 may include first nanocrystals 215, the second light absorption layer 220 may include second nanocrystals 225, and the third light absorption layer 230 may include third nanocrystals 235.

The sizes of the first, second and third nanocrystals 215, 225 and 235 may gradually increase toward the upper carrier transportation layer 120 or toward the lower carrier transportation layer 100. In some exemplary embodiments, the size of the first nanocrystals 215 may be less than that of the second nanocrystals 225 and the size of the third nanocrystals 235 may be greater than that of the second nanocrystals 225. Although the exemplary embodiments are described in conjunction with an example that the sizes of the first, second and third nanocrystals 215, 225 and 235 gradually increase toward the upper carrier transportation layer 120, the inventive concepts are not limited thereto. For example, the size of the first nanocrystals 215 may be greater than that of the second nanocrystals 225 and the size of the third nanocrystals 235 may be less than that of the second nanocrystals 225. That is, when the incident lights are irradiated onto a top surface of the third light absorption layer 230 opposite to the second light absorption layer 220, the size of the third nanocrystals 235 in the third light absorption layer 230 may be greater than those of the first and second nanocrystals 215 and 225 and the size of the first nanocrystals 215 in the first light absorption layer 210 may be less than those of the second and third nanocrystals 225 and 235. In contrast, when the incident lights are irradiated onto a bottom surface of the first light absorption layer 210 opposite to the second light absorption layer 220, the size of the first nanocrystals 215 in the first light absorption layer 210 may be greater than those of the second and third nanocrystals 225 and 235 and the size of the third nanocrystals 235 in the third light absorption layer 230 may be less than those of the first and second nanocrystals 215 and 225.

In some exemplary embodiments, it may be assumed that that first to third incident lights L1, L2 and L3 are irradiated onto the top surface of the third light absorption layer 230 opposite to the second light absorption layer 220. The wavelengths of the first to third incident lights L1, L2 and L3 may be different from each other. For example, the wavelength of the first incident light L1 may be greater than that of the second incident light L2 and the wavelength of the third incident light L3 may be less than that of the second incident light L2. In such a case, the first incident light L1 may have a less energy than the second and third incident lights L2 and L3, and the third incident light L3 may have a greater energy than the first and second incident lights L1 and L2.

If the first to third incident lights L1, L2 and L3 reach the third light absorption layer 230, the third light absorption layer 230 may absorb only a light having a specific wavelength determined by the size of the third nanocrystals 235. The third nanocrystals 235 may have larger sizes than the first and second nanocrystals 215 and 225. Thus, the first incident light L1 having the lowest energy may be absorbed into the third light absorption layer 230. Meanwhile, the second and third incident lights L2 and L3 may pass through the third light absorption layer 230 without absorption into the third light absorption layer 230 and/or reflection on the third light absorption layer 230.

If the second and third incident lights L2 and L3 reach the second light absorption layer 220, the second light absorption layer 220 may absorb only a light having a specific wavelength determined by the size of the second nanocrystals 225. The second nanocrystals 225 may have larger sizes than the first nanocrystals 215. Thus, the second incident light L2, which has the lower energy than the third incident light L3, may be absorbed into the second light absorption layer 220. Meanwhile, the third incident light L3 may pass through the second light absorption layer 220 without absorption into the second light absorption layer 220 and/or reflection on the second light absorption layer 220.

If the third incident lights L3 reach the first light absorption layer 210, the first light absorption layer 210 may absorb only a light having a specific wavelength determined by the size of the first nanocrystals 215. The first nanocrystals 215 may have smaller sizes than the second nanocrystals 225. Thus, the third incident light L3, which has the higher energy than the second incident light L2, may be absorbed into the first light absorption layer 210.

According to the exemplary embodiments, the photoelectric conversion layer 200 may include the plurality of stacked light absorption layers 210, 220 and 230 and each of the light absorption layers 210, 220 and 230 may include nanocrystals therein. In addition, the staked light absorption layers 210, 220 and 230 may be disposed such that the sizes of the nanocrystals are gradually reduced along a direction that the incident lights having different wavelengths travel. Thus, when the incident lights travel from a first surface of the photoelectric conversion layer 200 adjacent to the nanocrystals having relatively large sizes toward a second surface of the photoelectric conversion layer 200 adjacent to the nanocrystals having relatively small sizes, a relatively long wavelength incident light may be absorbed into the photoelectric conversion layer 200 adjacent to the first surface and a relatively short wavelength incident light may be absorbed into the photoelectric conversion layer 200 adjacent to the second surface. That is, the photoelectric conversion layer 200 according to the exemplary embodiments may absorb all the incident lights even though the incident lights have different wavelengths from each other. Accordingly, a light absorption efficiency of the photoelectric conversion layer 200 may be enhanced.

In addition, the photoelectric conversion layer 200 may be formed of a silicon nitride layer including silicon nanocrystals. That is, while the photoelectric conversion layer 200 is formed of a silicon nitride layer, the silicon nanocrystals may be formed in the silicon nitride layer. Thus, an annealing process required when a silicon oxide layer is formed may be omitted. Therefore, a fabrication process of the photo detector may be simplified. The silicon nitride layer used as the photoelectric conversion layer 200 has a narrower band gap than a silicon oxide layer. Thus, the electrons and holes generated in the photoelectric conversion layer 200 may easily move into the lower and upper carrier transportation layers 100 and 120, and interfacial defects between the silicon nitride layer and the silicon nanocrystals may be relatively reduced to minimize loss of the electrons and holes generated in the photoelectric conversion layer 200. As a result, a photoelectric conversion efficiency of the photoelectric conversion layer 200 may be enhanced.

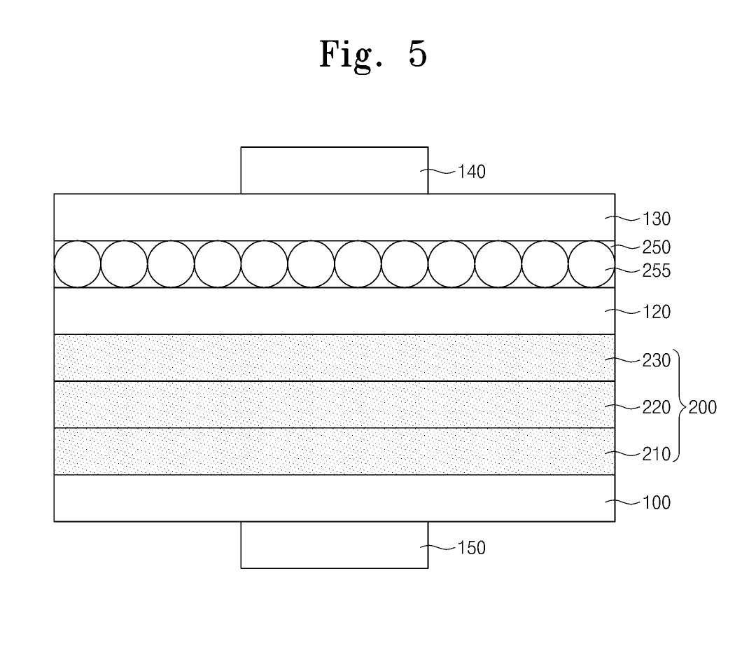

FIG. 5 is a cross sectional view illustrating a photo detector according to some exemplary embodiments.

Referring to FIG. 5, a photoelectric conversion layer 200, an upper carrier transportation layer 120 and a common electrode 130 may be sequentially stacked on a lower carrier transportation layer 100, as described with reference to FIG. 3.

The photoelectric conversion layer 200 may have a multi-layered structure. For example, the photoelectric conversion layer 200 may include a first light absorption layer 210, a second light absorption layer 220 and a third light absorption layer 230. The first, second and third light absorption layers 210, 220 and 230 may be sequentially stacked on the lower carrier transportation layer 100.

Each of the first, second and third light absorption layers 210, 220 and 230 may include silicon nanocrystals (Si-NCs). The silicon nanocrystals (Si-NCs) in the first, second and third light absorption layers 210, 220 and 230 may have different sizes from each other. The sizes of the Si-NCs in the first, second and third light absorption layers 210, 220 and 230 may be gradually reduced toward the lower carrier transportation layer 100. For example, the size of the Si-NCs in the second light absorption layer 220 may be less than that of the Si-NCs in the third light absorption layer 230, and the size of the Si-NCs in the first light absorption layer 210 may be less than that of the Si-NCs in the second light absorption layer 220.

A metal particle layer 250 may be disposed between the upper carrier transportation layer 120 and the common electrode 130. The metal particle layer 250 may contain metal particles 255, and the metal particles 255 may include at least one species of gold (Au) particles, silver (Ag) particles and aluminum (Al) particles. The metal particles 255 in the metal particle layer 250 may have a size of about 1 nanometer to about 1000 nanometers. The metal particles 255 may have diverse shapes such as circle shapes, oval shapes or rod shapes when viewed from a cross sectional view. The metal particle layer 250 may be formed using a physical vapor deposition (PVD) process or a chemical vapor deposition (CVD) process. An amount of the incident lights absorbed into the photoelectric conversion layer 200 may be controlled by the thickness of the metal particle layer 250, a material of the metal particles 255 and a shape of the metal particles 255.

An upper electrode 140 may be additionally disposed on the common electrode 130 opposite to the metal particle layer 250, and a lower electrode 150 may be additionally disposed under the lower carrier transportation layer 100 opposite to the photoelectric conversion layer 200. Each of the upper and lower electrodes 140 and 150 may include a conductive material. For example, each of the upper and lower electrodes 140 and 150 may include a metallic material such as nickel (Ni) or gold (Au).

If incident lights are irradiated onto the photo detector according to the present exemplary embodiment, the incident lights may pass through the common electrode 130 to reach the metal particle layer 250. The incident lights may be then introduced into the metal particle layer 250. The incident lights introduced into the metal particle layer 250 may be scattered and/or diffracted due to the presence of the metal particles 255 or a surface plasmon phenomenon may occurs because of the presence of the metal particles 255. Accordingly, the metal particle layer 250 may increase a probability or a possibility that the incident lights are introduced into the photoelectric conversion layer 200 without any reflection. As a result, a light absorption efficiency of the photo detector may be remarkably increased.

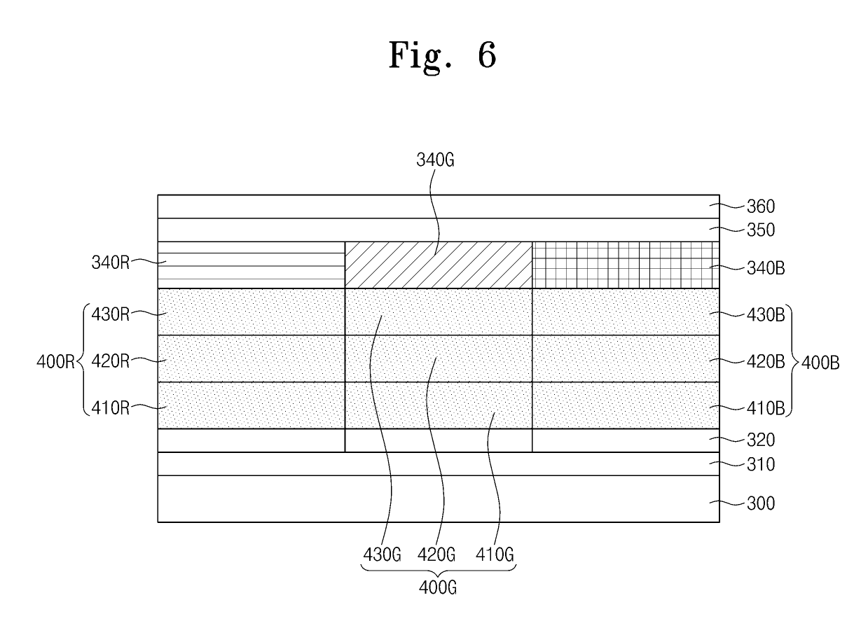

FIG. 6 is a cross sectional view illustrating a photo detector according to some exemplary embodiments.

Referring to FIG. 6, an insulation layer 310 may be disposed on a semiconductor substrate 300, and means for transporting charges may be disposed in the insulation layer 310. A plurality of pixel electrodes 320 may be disposed on the insulation layer 310. The pixel electrodes 320 may be disposed to correspond to respective ones of unit pixels. The pixel electrodes 320 may be electrically insulated from each other and each of the pixel electrodes 320 may include a conductive material.

Photoelectric conversion layers 400R, 400G and 400B may be disposed on respective ones of the pixel electrodes 320. The photoelectric conversion layer 400R may absorb a red light to covert the red light into an electrical signal, the photoelectric conversion layer 400G may absorb a green light to covert the green light into an electrical signal, and the photoelectric conversion layer 400B may absorb a blue light to covert the blue light into an electrical signal. Each of the photoelectric conversion layers 400R, 400G and 400B may have a multi-layered structure, as described with reference to FIGS. 3 and 5. In some exemplary embodiments, each of the photoelectric conversion layers 400R, 400G and 400B may include a first light absorption layer 410, a second light absorption layer 420 and a third light absorption layer 430. For example, the photoelectric conversion layer 400R may include first to third light absorption layers 410R, 420R and 430R sequentially stacked on one pixel electrode 320, and the photoelectric conversion layer 400G may also include first to third light absorption layers 410G, 420G and 430G sequentially stacked on another pixel electrode 320. Similarly, the photoelectric conversion layer 400B may include first to third light absorption layers 410B, 420B and 430B sequentially stacked on the other pixel electrode 320.

Each of the first to third light absorption layers 410, 420 and 430 may include silicon nanocrystals (Si-NCs). The silicon nanocrystals in the first light absorption layers 410R, 410G and 410B may have different sizes from the silicon nanocrystals in the second light absorption layers 420R, 420G and 420B. Further, the silicon nanocrystals in the third light absorption layers 430R, 430G and 430B may have different sizes from the silicon nanocrystals in the second light absorption layers 420R, 420G and 420B. In addition, the silicon nanocrystals in the third light absorption layers 430R, 430G and 430B may have different sizes from the silicon nanocrystals in the first light absorption layers 410R, 410G and 410B. In some exemplary embodiments, the sizes of the Si-NCs in the first, second and third light absorption layers 410, 420 and 430 may be gradually reduced toward the pixel electrode 320. That is, the sizes of the Si-NCs in the second light absorption layers 420R, 420G and 420B may be less than the sizes of the Si-NCs in the third light absorption layers 430R, 430G and 430B, and the sizes of the Si-NCs in the first light absorption layers 410R, 410G and 410B may be less than the sizes of the Si-NCs in the second light absorption layers 420R, 420G and 420B.

A red color filter 340R, a green color filter 340G and a blue color filter 340B may be disposed on the corresponding photoelectric conversion layers 400R, 400G and 400B, respectively. The color filters 340R, 340G and 340B may be covered with a common electrode 350 facing the pixel electrodes 320. The common electrode 350 may include a transparent material such as SnO₂, TiO₂, InO₂ or indium tin oxide (ITO), but not limited thereto. The common electrode 350 may be formed using a coating technique, for example, a spraying process, a spin coating process, a dipping process, a printing process, a doctorbalde coating process, a sputtering process or an electrophoresis process. The common electrode 350 may be electrically grounded to fix surface potentials of the photoelectric conversion layers 400R, 400G and 400B. A passivation layer 360 may be additionally disposed on the common electrode 350 opposite to the color filters 340R, 340G and 340B.

According to the exemplary embodiments set forth above, a photo detector may include a photoelectric conversion layer and the photoelectric conversion layer may have a plurality of staked light absorption layers. Each of the stacked light absorption layers may include nanocrystals, and the stacked light absorption layers may be disposed such that the sizes of the nanocrystals in the stacked light absorption layers are gradually reduced along a direction that the incident lights travel. Thus, when incident lights having different wavelengths travel along a direction from the light absorption layer having the largest nanocrystals toward the light absorption layer having the smallest nanocrystals, a relatively longest wavelength incident light may be absorbed into the light absorption layer having the largest nanocrystals and a relatively shortest wavelength incident light may be absorbed into the photoelectric conversion layer having the smallest nanocrystals. That is, the photoelectric conversion layer according to the exemplary embodiments may absorb all the incident lights even though the incident lights have different wavelengths from each other. Accordingly, a light absorption efficiency of the photo detector may be enhanced.

In addition, the photoelectric conversion layer may be formed of a silicon nitride layer including silicon nanocrystals. The silicon nanocrystals may be quantized to enhance a photoelectric conversion efficiency of the photoelectric conversion layer. In the event that the photoelectric conversion layer is formed of a silicon nitride layer, the photoelectric conversion layer may have a narrower band gap than a silicon oxide layer. Thus, electrons and holes generated in the photoelectric conversion layer may be more readily moved into electrode layers adjacent to the photoelectric conversion layer. Further, interfacial defects between the silicon nitride layer and the silicon nanocrystals may be relatively reduced to minimize loss of the electrons and holes generated in the photoelectric conversion layer. As a result, high performance image sensors may be provided.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A photo detector comprising:
a photoelectric conversion layer between a lower carrier transportation layer and an upper carrier transportation layer; and
a common electrode on the upper carrier transportation layer opposite to the photoelectric conversion layer,
wherein the photoelectric conversion layer includes a plurality of light absorption layers and each of the light absorption layers contains silicon nanocrystals; and
wherein the silicon nanocrystals in respective ones of the light absorption layers have different sizes from each other.

2. The photo detector of claim 1, wherein a size of the silicon nanocrystals in each light absorption layer is gradually increased as the light absorption layer becomes closer to the common electrode.

3. The photo detector of claim 1, wherein each of the light absorption layers include a silicon nitride layer containing the silicon nanocrystals.

4. The photo detector of claim 1, further comprising a metal particle layer between the upper carrier transportation layer and the common electrode,
wherein the metal particle layer includes metal particles having a size of about a few nanometers to about several hundreds of nanometers.

5. The photo detector of claim 4, wherein the metal particle layer includes at least one species of gold particles, silver particles and aluminum particles.

6. The photo detector of claim 1, wherein the lower carrier transportation layer includes a semiconductor material doped with impurities of a first conductivity type.

7. The photo detector of claim 6, wherein the upper carrier transportation layer includes a semiconductor material doped with impurities of a second conductivity type opposite to the first conductivity type.

8. The photo detector of claim 1, wherein the upper carrier transportation layer includes a silicon carbide type material.

9. The photo detector of claim 1, wherein the common electrode is a conductive electrode including indium tin oxide (ITO), SnO₂, In₂O₃, Cd₂SnO₄ or ZnO.

10. The photo detector of claim 1, further comprising:
an upper electrode on the common electrode; and
a lower electrode under the lower carrier transportation layer,
wherein each of the upper and lower electrodes includes nickel or gold.

11. A photo detector comprising:
a first light absorption layer, a second light absorption layer and a third light absorption layer sequentially stacked on a lower carrier transportation layer; and
an upper carrier transportation layer on the third light absorption layer,
wherein the first light absorption layer includes first nanocrystals having a first size, the second light absorption layer includes second nanocrystals having a second size greater than the first size, and the third light absorption layer includes third nanocrystals having a third size greater than the second size.

12. The photo detector of claim 11, wherein incident lights are irradiated onto a top surface of the upper carrier transportation layer opposite to the third light absorption layer.

13. The photo detector of claim 11, wherein each of the first to third light absorption layers includes a silicon nitride layer.

14. The photo detector of claim 11, wherein the first to third nanocrystals are silicon nanocrystals.
